(19) United States
(12) Patent Application Publication
(10) Pub. No.: US 2026/0123083 A1
(43) Pub. Date: Apr. 30, 2026

(54) IMAGE SENSOR

(71) Applicant: Samsung Electronics Co., Ltd., Suwon-si (KR)

(72) Inventors: Ji Hyun KWAK, Suwon-si (KR); Jong Hyun GO, Suwon-si (KR); Jin Young KIM, Suwon-si (KR); Gyun Ha PARK, Suwon-si (KR); Chang Kyu LEE, Suwon-si (KR)

(73) Assignee: Samsung Electronics Co., Ltd., Suwon-si (KR)

(21) Appl. No.: 19/352,718

(22) Filed: Oct. 8, 2025

(30) Foreign Application Priority Data
Oct. 29, 2024 (KR) 10-2024-0149316

(51) Int. Cl. H10F 39/00

(52) U.S. Cl. CPC H10F 39/809; H10F 39/811

(57) ABSTRACT

Provided is an image sensor. The image sensor includes a first substrate including first and second surfaces, opposite to each other, a surface insulating film, a first wiring structure including a first wiring and a first inter-wire insulating layer, a first via trench in the first substrate extended into the surface insulating film and including a pad pattern, a second via trench in the first substrate connected to the first via trench, a through via structure connected to the pad pattern in the second via trench, and a separation structure, filling a separation pattern trench, around the through via structure, the separation structure including a first separation pattern around a sidewall of the first via trench, and a second separation pattern between the sidewall of the first via trench and a sidewall of the second via trench, and the second separation pattern spaced apart from the through via structure.

### CROSS-REFERENCE TO RELATED APPLICATION

This application claims priority from Korean Patent Application No. 10-2024-0149316 filed on Oct. 29, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to image sensors.

### Description of the Related Art

An image sensor is one of semiconductor devices that may convert optical information into an electrical signal. The image sensor may include a charge coupled device (CCD) image sensor and a complementary metal-oxide semiconductor (CMOS) image sensor.

The image sensor may be configured in the form of a package, and at this time, the package may be configured in a structure that protects the image sensor and at the same time allows light to be incident on a photo receiving surface or a sensing area of the image sensor.

### BRIEF SUMMARY

Object of the present disclosure are to provide image sensors with improved product reliability.

An image sensor according to some example embodiments of the present disclosure for achieving the above technical objects includes a first substrate including a first surface and a second surface, which are opposite to each other, a surface insulating film on the first surface of the first substrate, a first wiring structure including a first wiring and a first inter-wire insulating layer on the second surface of the first substrate, a first via trench, defined by the first substrate, at least partially extended into the surface insulating film and the first substrate, a second via trench, defined by the first substrate, connected to the first via trench and extended into the first substrate, exposing at least a portion of the first wiring, a pad pattern in the first via trench, a through via structure connected to the pad pattern in the second via trench, and a separation structure, filling a separation pattern trench extended into the first substrate, around the through via structure, the separation structure including a first separation pattern around a sidewall of the first via trench, and a second separation pattern between the sidewall of the first via trench and a sidewall of the second via trench, and the second separation pattern spaced apart from the through via structure.

An image sensor according to some example embodiments of the present disclosure for achieving the above technical objects includes a first substrate including a first region and a second region around the first region, and including a first surface and a second surface, which are opposite to each other, photoelectric conversion layers in the first substrate of the first region, a first separation structure between the photoelectric conversion layers, the first separation structure filling a first separation pattern trench extended into the first substrate, a surface insulating film on the first surface of the first substrate, a first wiring structure on the second surface of the first substrate, the first wiring structure including a first wiring and a first inter-wire insulating layer, a first via trench defined by first substrate in the second region, the first via trench at least partially extended into the surface insulating film and the first substrate, a second via trench defined by the first substrate and connected to the first via trench and extended into the first substrate, exposing at least a portion of the first wiring, a pad pattern in the first via trench, a through via structure connected to the pad pattern in the second via trench, and a second separation structure, filling a second separation pattern trench extended into the first substrate, around the through via structure, the second separation structure including a first separation pattern around a sidewall of the first via trench, and a second separation pattern between the sidewall of the first via trench and a sidewall of the second via trench, and each of the first and second separation patterns includes a material different from that of the surface insulating film.

An image sensor according to some example embodiments of the present disclosure for achieving the above technical objects includes a first substrate including a pixel array region, a light blocking region and a pad region, and including a first surface and a second surface, which are opposite to each other, photoelectric conversion layers in the first substrate of the pixel array region, a first separation structure between the photoelectric conversion layers a surface insulating film on the first surface of the first substrate, grid patterns on the surface insulating film, a color filter on the grid patterns, a micro-lens on the color filter, a first wiring structure on the second surface of the first substrate, the first wiring structure including a first wiring and a first inter-wire insulating layer, a second substrate on the first wiring structure, the second substrate including a third surface facing the second surface and a fourth surface opposite to the third surface, a second wiring structure on the third surface of the second substrate, the second wiring structure including a second wiring and a second inter-wire insulating layer, a third substrate on the second wiring structure, the third substrate including a fifth surface facing the fourth surface and a sixth surface opposite to the fifth surface, a third wiring structure on the fifth surface of the third substrate, the third wiring structure including a third wiring and a third inter-wire insulating layer, a first via trench defined by the pad region, which is at least partially extended into the surface insulating film and the first substrate, a second via trench exposing and defined by at least a portion of the first wiring connected to the first via trench and extended into the first substrate, a pad pattern in the first via trench, a through via structure connected to the pad pattern in the second via trench, and a second separation structure, filling a separation pattern trench extended into the first substrate, around the through via structure, the second separation structure including a first separation pattern around a sidewall of the first via trench, and a second separation pattern between the sidewall of the first via trench and a sidewall of the second via trench, and when viewed in a plan view, the second separation pattern is inside the first separation pattern, and the through via structure is inside the second separation pattern.

An image sensor according to some example embodiments of the present disclosure for achieving the above technical objects includes a first substrate, a surface insulating film on a first surface of the first substrate, a first wiring structure below the first substrate, a via trench defined by the first substrate, penetrating the first substrate and having an upper portion and a lower portion, the upper portion being wider than the lower portion, a pad pattern in the upper portion, a through via structure in the lower portion connected to the pad pattern, and a separation structure including a first separation pattern around the pad pattern, and a second separation pattern under the pad pattern and around the through via structure, separated from the through via structure by a portion of the first substrate, each of the first and second separation patterns includes a material different from that of the surface insulating film.

An image sensor according to some example embodiments of the present disclosure for achieving the above technical objects wherein the through via structure physically contacts the first wiring structure through the via trench.

The objects of the present disclosure are not limited to those mentioned above, and additional objects of the present disclosure, which are not mentioned herein, will be clearly understood by those skilled in the art from the following description of the present disclosure.

### BRIEF DESCRIPTION OF THE DRAWINGS

FIG. 1 is a block diagram illustrating an image sensing device according to some example embodiments;

FIG. 2 is an example circuit view illustrating a unit pixel of an image sensor according to some example embodiments;

FIG. 3 is a view illustrating a conceptual layout of an image sensor according to some example embodiments;

FIG. 4 is an example layout view illustrating an image sensor according to some example embodiments;

FIG. 5 is a cross-sectional view taken along lines A-A′, B-B′, C-C′ and D-D′ of FIG. 4; FIGS. 6 and 7 are views illustrating an example layout of a pad region of an image sensor according to some example embodiments;

FIG. 8 is a view illustrating a conceptual layout of an image sensor according to some example embodiments;

FIGS. 9 to 11 are cross-sectional views illustrating an image sensor according to some example embodiments;

FIGS. 12 and 13 are views illustrating an example layout of a pad region of an image sensor according to some example embodiments.

### DETAILED DESCRIPTION OF THE DISCLOSURE

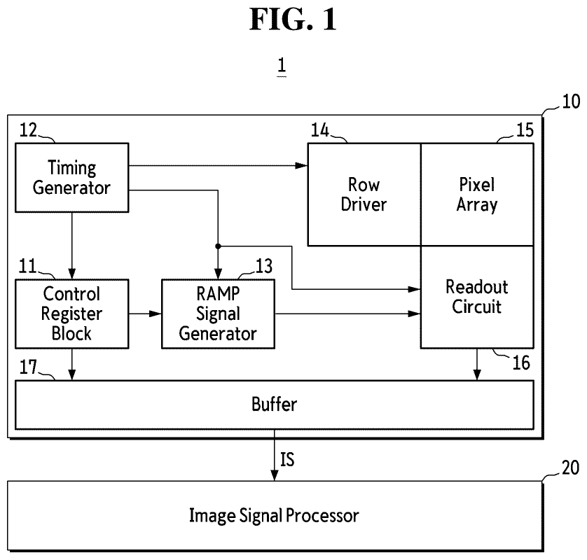

FIG. 1 is a block diagram illustrating an image sensing device according to some example embodiments.

Referring to FIG. 1, an image sensing device 1 according to some example embodiments may include an image sensor 10 and an image signal processor 20.

The image sensor 10 may generate an image signal IS by sensing an image of a sensing target using light. In some example embodiments, the generated image signal IS may be, for example, a digital signal, but some example embodiments according to technical spirits of the present disclosure are not limited thereto.

The image signal IS may be provided to the image signal processor 20 and then processed by the image signal processor 20. The image signal processor 20 may receive the image signal IS output from a buffer 17 of the image sensor 10 and process the received image signal IS to be more easily displayed.

In some example embodiments, the image signal processor 20 may perform digital binning for the image signal IS output from the image sensor 10. At this time, the image signal IS output from the image sensor 10 may be a raw image signal from a pixel array 15 without analog binning, or may be the image signal IS for which analog binning has been already performed.

In some example embodiments, the image sensor 10 and the image signal processor 20 may be disposed to be separated from each other as shown. For example, the image sensor 10 may be embedded in a first chip, and the image signal processor 20 may be embedded in a second chip, whereby the image sensor 10 and the image signal processor 20 may perform communication with each other through a predetermined (or, alternatively, desired or selected) interface. However, some example embodiments are not limited to this example, and the image sensor 10 and the image signal processor 20 may be implemented by one package, for example, a multi-chip package (MCP).

The image sensor 10 may include a pixel array 15, a control register block 11, a timing generator 12, a row driver 14, a readout circuit 16, a ramp signal generator 13, and a buffer 17.

The control register block 11 may control an overall operation of the image sensor 10. Particularly, the control register block 11 may directly transmit an operation signal to the timing generator 12, the ramp signal generator 13 and the buffer 17.

The timing generator 12 may generate a reference signal that becomes a reference of an operation timing of various elements of the image sensor 10. The operation timing reference signal generated by the timing generator 12 may be transferred to the ramp signal generator 13, the row driver 14, the readout circuit 16, etc.

The ramp signal generator 13 may generate and transmit a ramp signal used in the readout circuit 16. For example, the readout circuit 16 may include a correlation double sampler (CDS), a comparator, etc. The ramp signal generator 13 may generate and transmit a ramp signal used in the correlation double sampler (CDS), the comparator, etc.

The row driver 14 may selectively enable rows of the pixel array 15. The pixel array 15 may sense an external image. The pixel array 15 may include a plurality of pixels.

The readout circuit 16 may sample a pixel signal provided from the pixel array 15, compare the sampled pixel signal with the ramp signal and then convert an analog image signal (data) into a data image signal (data) based on the compared result.

The buffer 17 may include, for example, a latch. The buffer 17 may temporarily store the image signal IS that will be provided to the outside, and may transmit the image signal IS to an external memory or an external device.

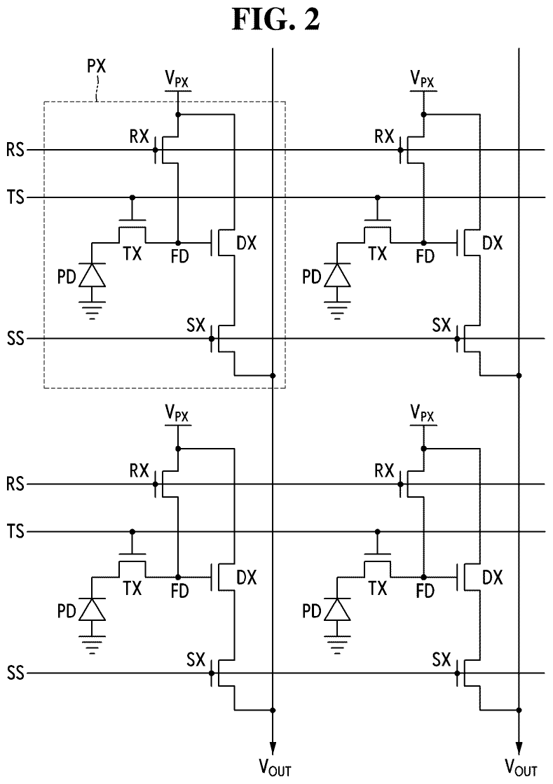

FIG. 2 is an example circuit view illustrating a unit pixel of an image sensor according to some example embodiments.

Referring to FIG. 2, the image sensor according to some example embodiments includes a plurality of unit pixels PX.

The plurality of unit pixels PX may be arranged two-dimensionally (e.g., in the form of a matrix, lattice, or regular pattern). Each unit pixel PX may include a photoelectric conversion layer PD, a transmission transistor TX, a floating diffusion region FD, a reset transistor RX, a drive transistor DX, and a selection transistor SX.

The photoelectric conversion layer PD may generate charges in proportion to the amount of light incident from the outside. The photoelectric conversion layer PD may be coupled with the transmission transistor TX that transmits charges, which are generated and then accumulated, to the floating diffusion region FD. Since the floating diffusion region FD is a region for converting charges into voltages and has a parasitic capacitance, the charges may be cumulatively stored in the floating diffusion region FD.

One end of the transmission transistor TX may be connected to the photoelectric conversion layer PD, and the other end of the transmission transistor TX may be connected to the floating diffusion region FD. The transmission transistor TX may be formed of a transistor driven by a predetermined (or, alternatively, desired or selected) bias (e.g., transmission signal TS). That is, the transmission transistor TX may transmit the charges generated from the photoelectric conversion layer PD to the floating diffusion region FD in accordance with the transmission signal TS.

The drive transistor DX may be provided as a source follower buffer amplifier. The drive transistor DX may amplify a change in an electric potential of the floating diffusion region FD that has received the charges from the photoelectric conversion layer PD, and may output the amplified change in the electric potential to an output line VOUT. When the drive transistor DX is turned on, a pixel power voltage VPX provided to a drain of the drive transistor DX may be transferred to a drain region of the selection transistor SX.

The selection transistor SX may select a unit pixel to be read in a row unit. The selection transistor may be a transistor that is driven by a selection line that applies a predetermined (or, alternatively, desired or selected) bias (e.g., row selection signal SS).

The reset transistor RX may periodically reset the floating diffusion region FD. The reset transistor RX may be a transistor driven by a reset line that applies a predetermined (or, alternatively, desired or selected) bias (e.g., reset signal RS). When the reset transistor RX is turned on by the reset signal RS, a predetermined (or, alternatively, desired or selected) electrical potential provided to the drain of the reset transistor RX, for example, the pixel power voltage VPX may be transferred to the floating diffusion region FD so that the floating diffusion region FD may be reset.

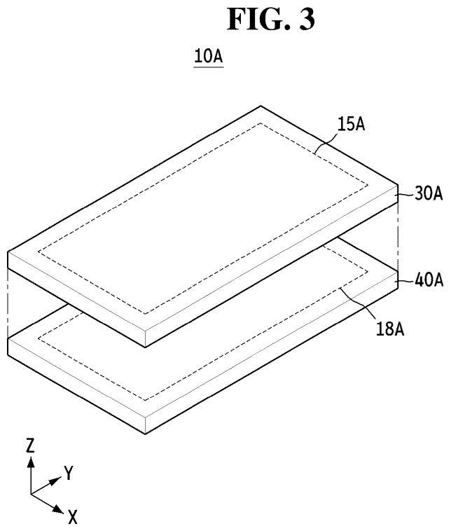

FIG. 3 is a view illustrating a conceptual layout of an image sensor according to some example embodiments.

Referring to FIG. 3, an image sensor 10A according to some example embodiments may include a first layer 30A and a second layer 40A. The second layer 40A and the first layer 30A may be stacked in a third direction Z and electrically connected to each other.

The first layer 30A may include a pixel array 15A in which a plurality of photoelectric conversion layers PD are disposed in a two-dimensional array structure. The pixel array 15A may correspond to the pixel array 15 of FIG. 1.

The second layer 40A may include a logic region 18A in which logic devices are disposed. The logic devices included in the logic region 18A may be electrically connected to the pixel array 15A to provide a signal to the pixel or process a signal output from the pixel. The logic region 18A may include at least one of, for example, the control register block 11, the timing generator 12, the ramp signal generator 13, the row driver 14, the readout circuit 16 or the buffer 17 of FIG. 1.

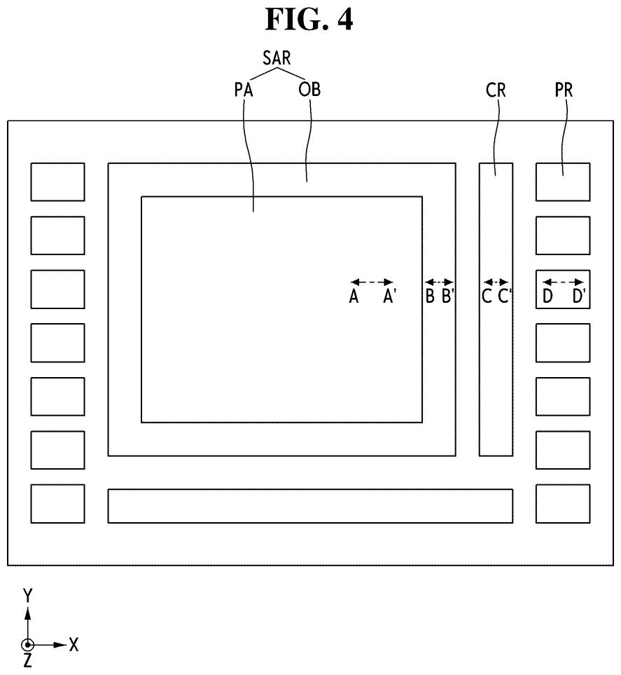

FIG. 4 is an example layout view illustrating an image sensor according to some example embodiments.

Referring to FIG. 4, the image sensor according to some example embodiments includes a sensor array region SAR, a connection region CR, and a pad region PR.

The sensor array region SAR may include a pixel array region PA corresponding to the pixel array 15 of FIG. 1. The sensor array region SAR may include a pixel array region PA and a light blocking region OB. Active pixels for receiving light to generate an active signal may be arranged in the pixel array region PA. Optical black pixels for shielding light to generate an optical black signal may be arranged in the light blocking region OB. The light blocking region OB may be disposed along the periphery of the pixel array region PA, but this is only exemplary.

In some example embodiments, dummy pixels may be disposed in the pixel array region adjacent to the light blocking region OB.

The connection region CR may be disposed in the periphery of the sensor array region SAR. The connection region CR may be disposed one side of the sensor array region SAR, but this is only exemplary. A connection structure (not shown) and lines may be disposed in the connection region CR to transmit and receive the electrical signal of the sensor array region SAR.

The pad region PR may be disposed in the periphery of the sensor array region SAR.

The pad region PR may be formed to be adjacent to an edge of the image sensor according to some example embodiments, but this is only exemplary. The pad region PR may be connected to an external device or the like to transmit and receive an electrical signal between the image sensor according to some example embodiments and the external device.

In FIG. 4, the connection region CR is shown as being interposed between the sensor array region SAR and the pad region PR, but is only exemplary. There may be various arrangements of the sensor array region SAR, the connection region CR, and the pad region PR as desired.

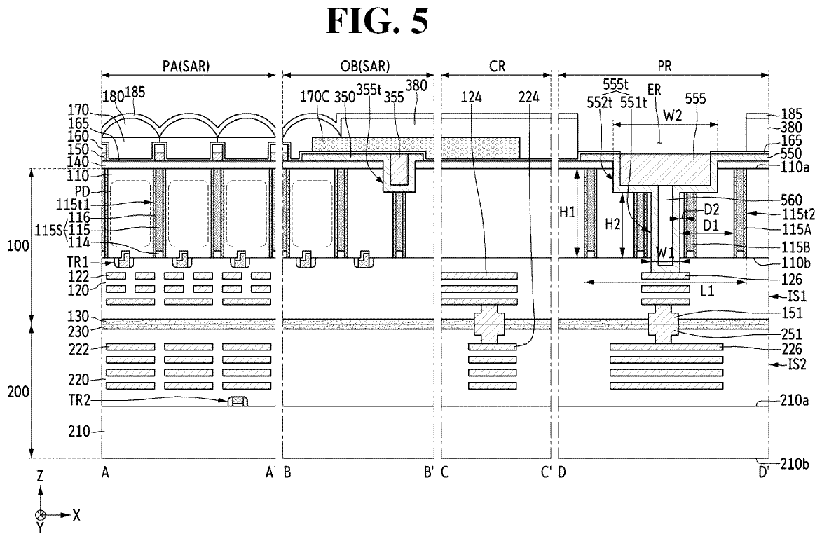

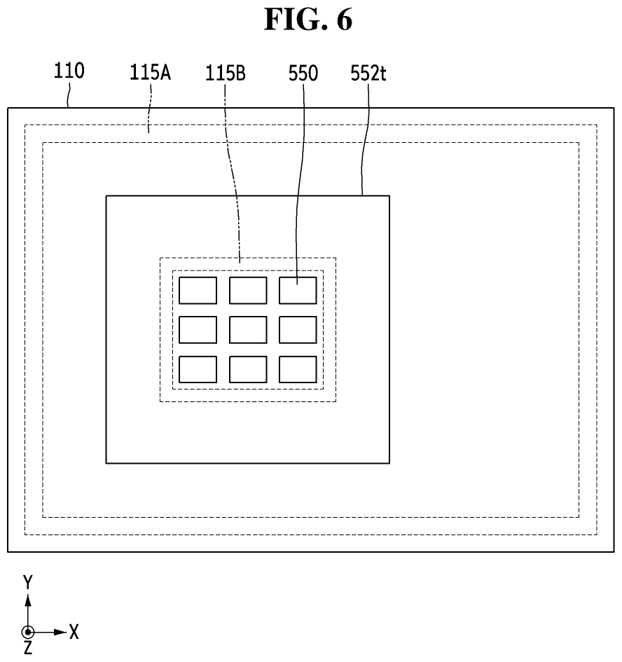

FIG. 5 is a cross-sectional view taken along lines A-A′, B-B′, C-C′ and D-D′ of FIG. 4. FIGS. 6 and 7 are views illustrating an example layout of a pad region of an image sensor according to some example embodiments.

Referring to FIG. 5, the image sensor according to some example embodiments may include a first substrate 110, a first wiring structure IS1, a photoelectric conversion layer PD, a first separation structure 115S, a surface insulating film 140, a color filter 170, grid patterns 150 and 160, a micro-lens 180, a contact film 350, a contact pattern 355, a through via structure 550, a pad pattern 555, second separation structures 115A and 115B, a second substrate 210 and a second wiring structure IS2.

The first substrate 110 may be a semiconductor substrate. For example, the first substrate 110 may be a bulk silicon or a silicon-on-insulator (SOI). The first substrate 110 may be a silicon substrate, or may include other materials such as silicon germanium, indium antimonide, lead telluride, indium arsenide, indium phosphide, gallium arsenide and/or gallium antimonide. Alternatively, the first substrate 110 may be an epitaxial layer formed on a base substrate.

The first substrate 110 may include a first surface 110a and a second surface 110b, which are opposite to each other. The first surface 110a may be referred to as a back side of the first substrate 110, and the second surface 110b may be referred to as a front side of the first substrate 110. In some example embodiments, the first surface 110a of the first substrate 110 may be a light receiving surface on which light is incident. That is, the image sensor according to some example embodiments may be a backside illumination (BSI) image sensor.

The first substrate 110 may be extended in a first direction X and a second direction Y, respectively, which cross each other. The first direction X and the second direction Y may mean horizontal directions perpendicular to each other. A third direction Z may mean a height direction perpendicular to each of the first direction X and the second direction Y.

A plurality of unit pixel regions may be disposed in the first substrate 110 of the sensor array region SAR. For example, a plurality of pixel regions arranged two-dimensionally (e.g., in the form of a matrix) on a plane including the first direction X and the second direction Y may be formed in the pixel array region PA.

Each unit pixel region may include a photoelectric conversion layer PD. The photoelectric conversion layer PD may be disposed in the first substrate 110 of the pixel array region PA. The photoelectric conversion layer PD may generate charges in proportion to the amount of light incident from the outside. In some example embodiments, the photoelectric conversion layer PD may not be disposed in a portion of the light blocking region OB. For example, the photoelectric conversion layer PD may be disposed in the first substrate 110 of the light blocking region OB adjacent to the pixel array region PA, but may not be disposed in the first substrate 110 of the light blocking region OB spaced apart from the pixel array region PA.

The photoelectric conversion layer PD may include at least one of, for example, a photo diode, a photo transistor, a photo gate, a pinned photo diode, an organic photo diode, a quantum dot, or their combination, but is not limited thereto.

Each unit pixel (PX of FIG. 2) may include a first transistor TR1. In some example embodiments, the first transistor TR1 may be disposed on the second surface 110b of the first substrate 110. The first transistor TR1 may be connected to the photoelectric conversion layer PD to constitute various transistors for processing an electrical signal. For example, the first transistor TR1 may be a transistor such as the transmission transistor, the reset transistor, the source follower transistor, or the selection transistor.

In some example embodiments, the first transistor TR1 may include a vertical transmission transistor. For example, a portion of the first transistor TR1 may be extended into the first substrate 110. The first transistor TR1 may reduce an area of a unit pixel to enable higher integration of the image sensor.

The first separation structure 115S may be disposed in the first substrate 110 of the sensor array region SAR. For example, the first separation structure 115S may be formed by burying an insulating material in a first trench 115t1 (deep trench) formed by patterning the first substrate 110.

The first separation structure 115S may define a plurality of unit pixel regions. When viewed in a plan view, the first separation structure 115S may be disposed in a grid shape to separate a plurality of unit pixel regions from each other.

The first separation structure 115S may pass through at least a portion of the first substrate 110. In some example embodiments, the first separation structure 115S may be extended from the second surface 110b to the first surface 110a.

In some example embodiments, the first separation structure 115S may include a spacer film 116, a filling film 115, and a capping film 114. The spacer film 116 may be extended along a side of the first trench 115t1. The filling film 115 may be disposed on the spacer film 116 to fill at least a portion of the first trench 115t1. The spacer film 116 may separate the filling film 115 from the first substrate 110. The capping film 114 may be disposed on the second surface 110b of the first substrate 110. A lower surface of the capping film 114 may be coplanar or substantially coplanar with the second surface 110b of the first substrate 110. The capping film 114 may be disposed on the filling film 115 to fill the remainder of the first trench 115t1.

The filling film 115 may include a conductive material. For example, the filling film 115 may include poly silicon, but is not limited thereto.

The spacer film 116 and the capping film 114 may include an insulating material. For example, each of the spacer film 116 and the capping film 114 may include at least one of silicon oxide, aluminum oxide, tantalum oxide or their combination, but is not limited thereto. The spacer film 116 may electrically insulate the filling film 115 from the first substrate 110. In some example embodiments, the spacer film 116 may include an oxide having a refractive index lower than that of the first substrate 110. The spacer film 116 having a refractive index lower than that of the first substrate 110 may refract or reflect light obliquely incident on the photoelectric conversion layer PD. Also, the spacer film 116 may prevent or reduce photocharges generated in a specific unit pixel by incident light from moving to adjacent unit pixel regions by random drift.

The first wiring structure IS1 may be disposed on the first substrate 110. For example, the first wiring structure IS1 may cover the second surface 110b of the first substrate 110. The first substrate 110 and the first wiring structure IS1 may constitute the first substrate structure 100. The first substrate structure 100 may correspond to the first layer 30A of FIG. 3.

The first wiring structure IS1 may be formed of one or a plurality of wirings. For example, the first wiring structure IS1 may include a first inter-wire insulating layer 120 and a plurality of wirings 122, 124 and 126 in the first inter-wire insulating layer 120. In the drawing, the number of layers and arrangement of wirings constituting the first wiring structure IS1 are only exemplary. The first inter-wire insulating layer 120 may include at least one of, for example, silicon oxide, silicon nitride, silicon oxynitride or a low dielectric constant (low-k) material having a dielectric constant lower than that of silicon oxide, but is not limited thereto.

In some example embodiments, the first wiring structure IS1 may include a first wiring 122 in the sensor array region SAR, a second wiring 124 in the connection region CR, and a third wiring 126 in the pad region PR. The first wiring 122 may be electrically connected to the unit pixel of the sensor array region SAR. For example, the first wiring 122 may be electrically connected to the first transistor TR1. The second wiring 124 may be extended from the sensor array region SAR. For example, the second wiring 124 may be electrically connected to at least a portion of the first wiring 122. Accordingly, the second wiring 124 may be electrically connected to the unit pixel of the sensor array region SAR. The third wiring 126 may be electrically connected to the pad pattern 555 of the pad region PR. The third wiring 126 may be connected to the pad pattern 555 through the through via structure 550.

The first wiring 122, the second wiring 124 and the third wiring 126 may include at least one of tungsten (W), copper (Cu), aluminum (Al), gold (Au), silver (Ag) or their alloy, but are not limited thereto.

The second substrate 210 may be a bulk silicon or a silicon-on-insulator (SOI). The second substrate 210 may be a silicon substrate, or may include other material such as silicon germanium, indium antimonide, lead telluride, indium arsenide, indium phosphide, gallium arsenide, and/or gallium antimonide. Alternatively, the second substrate 210 may be an epitaxial layer formed on a base substrate.

The second substrate 210 may include a third surface 210a and a fourth surface 210b, which are opposite to each other. In some example embodiments, the third surface 210a of the second substrate 210 may be a surface facing the second surface 110b of the first substrate 110.

A plurality of electronic devices may be disposed on the second substrate 210. For example, a second transistor TR2 may be disposed on the third surface 210a of the second substrate 210. The second transistor TR2 may be electrically connected to the sensor array region SAR to transmit and receive an electrical signal to and from each unit pixel of the sensor array region SAR. For example, the second transistor TR2 may include transistors constituting the control register block 11, the timing generator 12, the ramp signal generator 13, the row driver 14, the readout circuit 16 and/or the buffer 17 of FIG. 1.

The second wiring structure IS2 may be disposed on the second substrate 210. For example, the second wiring structure IS2 may cover the third surface 210a of the second substrate 210. The second substrate 210 and the second wiring structure IS2 may constitute the second substrate structure 200. The second substrate structure 200 may correspond to the second layer 40A of FIG. 3.

The second wiring structure IS2 may be formed of one or a plurality of wirings. For example, the second wiring structure IS2 may include a second inter-wire insulating layer 220 and a plurality of wirings 222, 224 and 226 in the second inter-wire insulating layer 220. In the drawing, the number of layers and the arrangement of wirings constituting the second wiring structure IS2 are only exemplary, and are not limited thereto. The second inter-wire insulating layer 220 may include at least one of, for example, silicon oxide, silicon nitride, silicon oxynitride or a low dielectric constant (low-k) material having a dielectric constant lower than that of silicon oxide, but is not limited thereto. In some example embodiments, the second wiring structure IS2 may include the same material as that of the first wiring structure IS1. At least a portion of the wirings 222, 224 and 226 of the second wiring structure IS2 may be connected to the second transistor TR2. In some example embodiments, the second wiring structure IS2 may include a fourth wiring 222 in the sensor array region SAR, a fifth wiring 224 in the connection region CR, and a sixth wiring 226 in the pad region PR. The fourth wiring 222, the fifth wiring 224 and the sixth wiring 226 may include at least one of, for example, tungsten (W), copper (Cu), aluminum (Al), gold (Au), silver (Ag) or their alloy, but are not limited thereto.

In some example embodiments, the first wiring structure IS1 may further include a first bonding layer 130. The first bonding layer 130 may be disposed on the first inter-wire insulating layer 120. The first bonding layer 130 may cover at least a portion of a lower surface of the first inter-wire insulating layer 120. The second wiring structure IS2 may further include a second bonding layer 230. The second bonding layer 230 may be disposed on the second inter-wire insulating layer 220. The second bonding layer 230 may cover at least a portion of an upper surface of the second inter-wire insulating layer 220. The second bonding layer 230 may be bonded to the first bonding layer 130. Accordingly, the second wiring structure IS2 may be attached to the first wiring structure IS1. For example, an upper surface of the second bonding layer 230 may be bonded to a lower surface of the first bonding layer 130.

For example, each of the first bonding layer 130 and the second bonding layer 230 may include at least one of silicon nitride or silicon carbonitride, but is not limited thereto.

A first bonding pad 151 exposed from the lower surface of the first inter-wire insulating layer 120 may be formed in the first bonding layer 130. Also, a second bonding pad 251, which corresponds to the first bonding pad 151 and is exposed from the upper surface of the second inter-wire insulating layer 220, may be formed in the second bonding layer 230. When the first bonding layer 130 and the second bonding layer 230 are attached to each other, the first bonding pad 151 may be electrically connected to the second bonding pad 251. Accordingly, the first substrate structure 100 and the second substrate structure 200 may be electrically connected to each other.

For example, the first bonding pad 151 and the second bonding pad 251 may include copper (Cu) and thus connected to each other in a Cu—Cu bonding method, but this is only exemplary. The first bonding pad 151 and the second bonding pad 251 may include aluminum (Al) and/or tungsten (W).

The first bonding pad 151 and the second bonding pad 251 are only shown as being formed in the connection region CR and the pad region PR, but this is only exemplary. For example, the first bonding pad 151 and the second bonding pad 251 may be formed in at least one of the pixel array region PA, the light blocking region OB, the connection region CR, or the pad region PR.

The surface insulating film 140 may be disposed on the first surface 110a of the first substrate 110. The surface insulating film 140 may be extended along the first surface 110a of the first substrate 110.

The surface insulating film 140 may include an insulating material. For example, the surface insulating film 140 may include at least one of silicon oxide, silicon nitride, silicon oxynitride, aluminum oxide, hafnium oxide or their combination, but is not limited thereto. Also, the surface insulating film 140 may be a multi-film. For example, the surface insulating film 140 may include an aluminum oxide film, a hafnium oxide film, a silicon nitride film, and a hafnium oxide film, which are sequentially stacked on the first surface 110a of the first substrate 110, but is not limited thereto.

The surface insulating film 140 functions as an anti-reflective film to prevent or reduce reflection of light incident on the first substrate 110, thereby improving a light receiving rate of the photoelectric conversion layer PD. Also, the surface insulating film 140 functions as a planarization film to form the color filter 170 and the micro-lens 180, which will be described later, at a uniform height.

The color filter 170 may be disposed on the surface insulating film 140. The color filter 170 may be arranged to correspond to each unit pixel region of the sensor array region SAR, but is not limited thereto.

The color filter 170 may have various color filters depending on unit pixels. For example, the color filter 170 may be arranged in a Bayer pattern including a red color filter, a green color filter, and a blue color filter. However, this is only exemplary, and the color filter 170 may include a yellow filter, a magenta filter, and a cyan filter.

In some example embodiments, the grid patterns 150 and 160 may be disposed between the color filters 170. The grid patterns 150 and 160 may be disposed on the surface insulating film 140. In some example embodiments, the grid patterns 150 and 160 may be disposed to overlap the first separation structure 115S in a vertical direction (e.g., the third direction Z).

In some example embodiments, the grid patterns 150 and 160 may include a conductive pattern 150 and a low refractive index pattern 160. The conductive pattern 150 and the low refractive index pattern 160 may be sequentially stacked on the surface insulating film 140, for example.

The conductive pattern 150 may include at least one of, for example, titanium (Ti), titanium nitride (TiN), tantalum Ta), tantalum nitride (TaN), tungsten (W), aluminum (Al) or copper (Cu), but is not limited thereto. The conductive pattern 150 may prevent or reduce charges generated by ESD or the like from being accumulated on a surface (for example, the first surface 110a) of the first substrate 110, thereby more effectively preventing or reducing an ESD bruise defect.

The low refractive index pattern 160 may include a low refractive index material having a refractive index lower than that of silicon (Si). For example, the low refractive index pattern 160 may include at least one of silicon oxide, aluminum oxide, tantalum oxide or their combination, but is not limited thereto. The low refractive index pattern 160 may improve quality of the image sensor by refracting or reflecting obliquely incident light to improve condensing light efficiency.

In some example embodiments, a first passivation film 165 may be disposed on the surface insulating film 140 and the grid patterns 150 and 160. For example, the first passivation film 165 may be extended to be conformal along a profile of an upper surface of the surface insulating film 140 and sides and upper surfaces of the grid patterns 150 and 160.

The first passivation film 165 may include, for example, aluminum oxide, but is not limited thereto. The first passivation film 165 may prevent or reduce damage to the surface insulating film 140 and the grid patterns 150 and 160.

The micro-lens 180 may be disposed on the color filter 170. The micro-lens 180 may be arranged to correspond to each unit pixel region of the sensor array region SAR.

The micro-lens 180 may have a convex shape, and may have a predetermined (or, alternatively, desired or selected) radius of curvature. Accordingly, the micro-lens 180 may condense light incident on the photoelectric conversion layer PD. The micro-lens 180 may include, for example, a light transmitting resin, but is not limited thereto.

In some example embodiments, a second passivation film 185 may be disposed on the micro-lens 180. The second passivation film 185 may be extended along a surface of the micro-lens 180. The second passivation film 185 may include, for example, an inorganic oxide film (e.g., silicon oxide, titanium oxide, zirconium oxide, hafnium oxide and their combination), but is not limited thereto. In some example embodiments, the second passivation film 185 may include low temperature oxide (LTO).

The second passivation film 185 may protect the micro-lens 180 from the outside. For example, the second passivation film 185 may include the inorganic oxide film to protect the micro-lens 180 containing an organic material. In addition, the second passivation film 185 may improve quality of the image sensor by improving the condensing efficiency of the micro-lens 180. For example, the second passivation film 185 may fill a space between the micro-lenses 180 to reduce reflection, refraction, scattering and the like of incident light reaching the space between the micro-lenses 180.

In some example embodiments, a contact film 350 may be disposed in the light blocking region OB. The contact film 350 may be disposed on the surface insulating film 140 of the light blocking region OB. The contact film 350 may be in contact with at least a portion of the first separation structure 115S.

For example, a contact trench 355t exposing the first separation structure 115S may be formed in the second substrate 210 and the surface insulating film 140 of the light blocking region OB. The contact film 350 may be disposed in the contact trench 355t to contact the first separation structure 115S in the light blocking region OB. In some example embodiments, the contact film 350 may be extended along the contact trench 355t. The contact film 350 may be extended along a profile of a side and a lower surface of the contact trench 355t.

The contact film 350 may include at least one of titanium (Ti), titanium nitride (TiN), tantalum (Ta), tantalum nitride (TaN), tungsten (W), aluminum (Al) or copper (Cu), but is not limited thereto.

The contact pattern 355 may be disposed on the contact film 350 to fill the contact trench 355t. The contact pattern 355 may include at least one of, for example, tungsten (W), copper (Cu), aluminum (Al), gold (Au), silver (Ag) or their alloy, but is not limited thereto. In some example embodiments, the contact pattern 355 may include a material different from that of the contact film 350. For example, the contact film 350 may include tungsten (W), and the contact pattern 355 may include aluminum (Al).

The contact film 350 may apply a ground voltage or a negative voltage to the filling film 115. In this case, an electrostatic discharge (ESD) bruise defect of the image sensor may be more effectively prevented or reduced. In this case, the ESD bruise defect refers to a phenomenon in which charges generated by the ESD or the like are accumulated in the first substrate 110 and thus a stain such as a bruise is generated in an image that is generated.

The first passivation film 165 may cover the contact film 350 and the contact pattern 355. For example, the first passivation film 165 may be extended along a profile of the contact film 350 and the contact pattern 355.

The through via structure 550 may be disposed in the pad region PR. The through via structure 550 may be disposed on the surface insulating film 140 of the pad region PR. The through via structure 550 may be electrically connected to the second wiring structure IS2 by passing through the first substrate 110 and the first wiring structure IS1. The through via structure 550 may electrically connect the second substrate structure 200 to an external device or the like.

For example, a via trench 555t exposing the third wiring 126 may be formed in the first substrate structure 100 of the pad region PR. The via trench 555t may include a first via trench 551t and a second via trench 552t.

The first via trench 551t may pass through a portion of the first substrate 110 and a portion of the first wiring structure IS1. The first via trench 551t may expose at least a portion of the third wiring 126. For example, the first via trench 551t may expose at least a portion of an upper surface of the third wiring 126. The first via trench 551t may have a first width W1.

The second via trench 552t may be disposed on the first via trench 551t. The second via trench 552t may be disposed in the surface insulating film 140 and the first substrate 110. The second via trench 552t may pass through a portion of the first substrate 110. The second via trench 552t may have a second width W2. The second width W2 may be greater than the first width W1. At least a portion of the first via trench 551t may overlap the second via trench 552t in the vertical direction Z. For example, the first via trench 551t may be disposed at the center of the second via trench 552t, but is not limited thereto.

The through via structure 550 may be disposed in the via trench 555t. The through via structure 550 may be extended along the via trench 555t. The through via structure 550 may be extended along a profile of a side and a lower surface of the via trench 555t. The through via structure 550 may be extended to be conformal along the via trench 555t, for example. The through via structure 550 may be in contact with the third wiring 126. The through via structure 550 may be electrically connected to the third wiring 126.

The through via structure 550 may be extended from an upper surface of the surface insulating film 140 to the third wiring 126. The pad pattern 555 may be disposed on the through via structure 550 to fill at least a portion of the via trench 555t. The pad pattern 555 may have an integral structure for filling the via trench 555t.

The through via structure 550 may be extended along at least a portion of the pad pattern 555 and electrically connected to the third wiring 126. The through via structure 550 may be extended along sides and a bottom surface of the pad pattern 555.

The pad pattern 555 and the through via structure 550 may include a metallic material. For example, the pad pattern 555 and the through via structure 550 may include at least one of tungsten (W), copper (Cu), aluminum (Al), gold (Au), silver (Ag) or their alloy, but are not limited thereto.

In some example embodiments, the first passivation film 165 may cover the through via structure 550. For example, the first passivation film 165 may be extended along a profile of the through via structure 550. In some example embodiments, the first passivation film 165 may expose the pad pattern 555.

In some example embodiments, the second separation structures 115A and 115B may be disposed in the first substrate 110. The second separation structures 115A and 115B may include a first separation pattern 115A disposed around a sidewall of the second via trench 552t and a second separation pattern 115B between a sidewall of the first via trench 551t and a sidewall of the second via trench 552t.

Each of the first separation pattern 115A and the second separation pattern 115B may be formed by burying an insulating material in a second trench (a deep trench) 115t2 formed by patterning the first substrate 110.

The second separation pattern 115B may be extended between the pad pattern 555 and the second surface 110b of the first substrate 110. The first separation pattern 115A may be extended between the surface insulating film 140 and the second surface 110b of the first substrate 110.

For example, the second trench 115t2 may be formed in the first substrate 110. The second trench 115t2 may be disposed on at least one side of the via trench 555t. The second trench 115t2 may be spaced apart from the via trench 555t. The second trench 115t2 may be extended from the first surface 110a of the first substrate 110 to the second surface 110b of the first substrate 110. Alternatively, the second trench 115t2 may be extended from at least one surface of the through via structure 550 to the second surface 110b of the first substrate 110.

In the third direction Z, a depth of the second trench 115t2 may be similar to or the same as a depth of the first trench 115t1. In the first direction X, a width of the second trench 115t2 may be similar to or the same as a width of the first trench 115t1.

The first separation pattern 115A may fill the second trench 115t2 extended from the first surface 110a of the first substrate 110 to the second surface 110b of the first substrate 110. The second separation pattern 115B may fill the second trench 115t2 extended from at least one surface of the through via structure 550 to the second surface 110b of the first substrate 110.

The first separation pattern 115A may be spaced apart from the through via structure 550. The second separation pattern 115B may be spaced apart from the through via structure 550. In the first direction X, a first distance D1 between the first separation pattern 115A and the through via structure 550 may be longer than a second distance D2 between the second separation pattern 115B and the through via structure 550.

A length of the first separation pattern 115A extended into the first substrate 110 may be different from a length of the second separation pattern 115B extended into the first substrate 110. In the third direction Z, a first length H1 of the first separation pattern 115A extended into the first substrate 110 may be longer than a second length H2 of the second separation pattern 115B extended into the first substrate 110.

For example, in the first direction X, a maximum distance L1 between the outermost walls of the first separation pattern 115A may be about or exactly 110 μm, but is not limited thereto.

Each of the first separation pattern 115A and the second separation pattern 115B may include the same material as that of the first separation structure 115S. Each of the first separation pattern 115A and the second separation pattern 115B may include a material different from that of the surface insulating film 140.

For example, each of the first separation pattern 115A and the second separation pattern 115B may include a spacer film 116, a filling film 115, and a capping film 114. The spacer film 116 may be extended along a side of the second trench 115t2. The filling film 115 may be disposed on the spacer film 116 to fill at least a portion of the second trench 115t2. The spacer film 116 may separate the filling film 115 from the first substrate 110. The capping film 114 may be disposed on the second surface 110b of the first substrate 110. The lower surface of the capping film 114 may be coplanar or substantially coplanar with the second surface 110b of the first substrate 110. The capping film 114 may be disposed on the filling film 115 to fill the remainder of the second trench 115t2.

The filling film 115 may include a conductive material. For example, the filling film 115 may include poly silicon, but is not limited thereto.

The spacer film 116 and the capping film 114 may include an insulating material. For example, each of the spacer film 116 and the capping film 114 may include at least one of silicon oxide, aluminum oxide, tantalum oxide or their combination, but is not limited thereto.

In some example embodiments, a light blocking filter 170C may be disposed on the contact film 350. For example, the light blocking filter 170C may cover a portion of the first passivation film 165 in the light blocking region OB and the connection region CR. The light blocking filter 170C may block light incident on the first substrate 110. The light blocking filter 170C may include, for example, a blue color filter.

In some example embodiments, a third passivation film 380 may be disposed on the light blocking filter 170C. For example, the third passivation film 380 may cover a portion of the first passivation film 165 in the light blocking region OB, the connection region CR, and the pad region PR. In some example embodiments, the second passivation film 185 may be extended along a surface of the third passivation film 380. For example, the third passivation film 380 may be extended along a surface of the light blocking filter 170C. The third passivation film 380 may include, for example, a light transmitting resin, but is not limited thereto. In some example embodiments, the third passivation film 380 may include the same material as that of the micro-lens 180.

In some example embodiments, the second passivation film 185 and the third passivation film 380 may expose the pad pattern 555. For example, an opening ER for exposing the pad pattern 555 may be formed in the second passivation film 185 and the third passivation film 380.

In some example embodiments, the pad pattern 555 connected to an external device or the like may apply a ground voltage or a negative voltage to the contact film 350. For example, the ground voltage or the negative voltage, which is applied from the pad pattern 555, may be applied to the contact film 350 through the through via structure 550, the sixth wiring 226, the fifth wiring 224 and the connection structure (not shown). The electrical signal generated from the photoelectric conversion layer PD may be transmitted to the outside through the first wiring 122, the second wiring 124, the fifth wiring 224, the sixth wiring 226, the through via structure 550 and the pad pattern 555. The pad pattern 555 may be an input/output pad of the image sensor according to some example embodiments.

In this case, parasitic capacitance may occur due to a potential difference between the pad pattern 555 containing a metallic material and the first substrate 110 containing silicon (Si). However, in some example embodiments, such parasitic capacitance may be reduced in such a manner that the second separation structures 115A and 115B are further disposed around the pad pattern 555 and the through via structure 550.

FIGS. 6 and 7 are views illustrating an example layout of a pad region of an image sensor according to some example embodiments. For convenience of description, redundant portions of those described with reference to FIGS. 1 to 5 will be briefly described or omitted.

When viewed in a plan view, the second separation pattern 115B may be disposed inside the first separation pattern 115A. When viewed in a plan view, the first separation pattern 115A may surround the second separation pattern 115B.

Referring to FIG. 6, when viewed in a plan view, a plurality of through via structures 550 may be disposed inside one second separation pattern 115B. When viewed in a plan view, the second separation pattern 115B may surround the plurality of through via structures 550.

The number and arrangement shape of the plurality of through via structures 550 are exemplary, and are not limited to those shown in the drawing.

Referring to FIG. 7, when viewed in a plan view, each through via structure 550 may be disposed inside each second separation pattern 115B. When viewed in a plan view, the second separation pattern 115B may surround one through via structure 550.

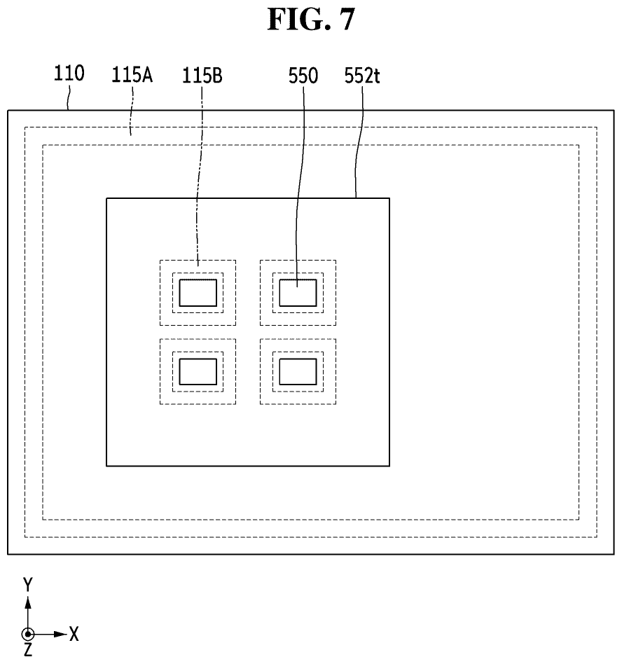

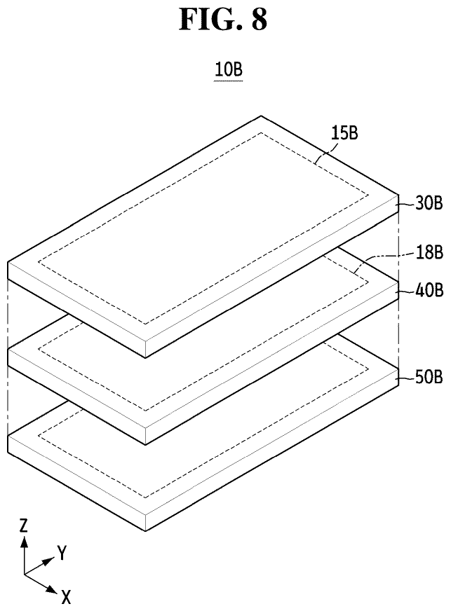

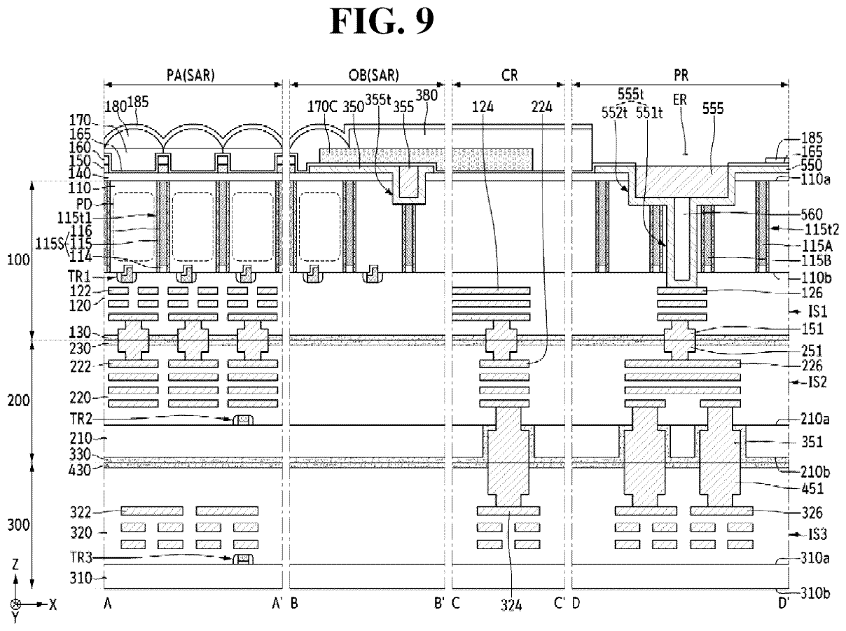

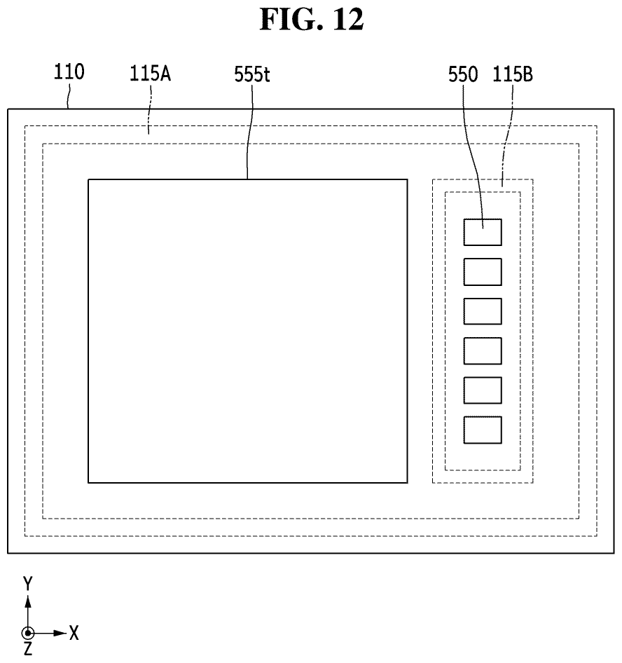

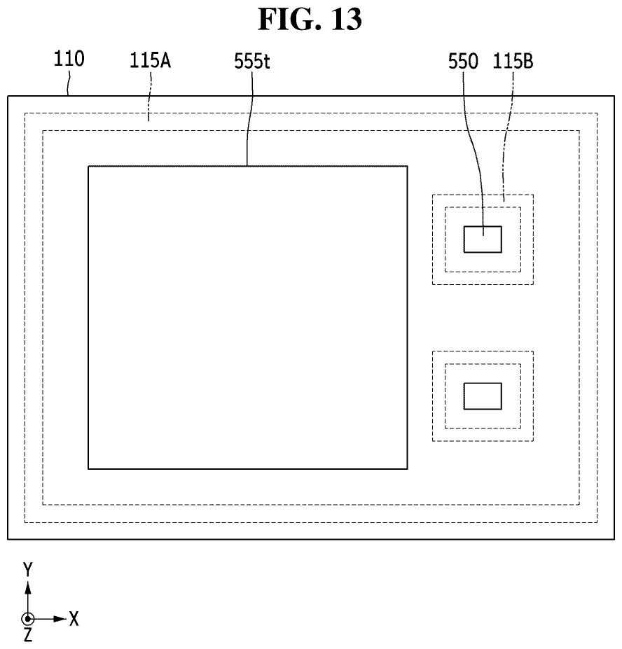

FIG. 8 is a view illustrating a conceptual layout of an image sensor according to some example embodiments. FIGS. 9 to 11 are cross-sectional views illustrating an image sensor according to some example embodiments. FIGS. 12 and 13 are views illustrating an example layout of a pad region of an image sensor according to some example embodiments. For convenience of description, redundant portions of those described with reference to FIGS. 1 to 7 will be briefly described or omitted.

Referring to FIG. 8, an image sensor 10B according to some example embodiments may include a first layer 30B, a second layer 40B, and a third layer 50B. The third layer 50B, the second layer 40B and the first layer 30B may be stacked in the third direction Z.

The first layer 30B may include a photodiode array 15B in which a plurality of photoelectric conversion layers PD are disposed in a two-dimensional array structure.

The second layer 40B may include a transistor region 18B in which a plurality of transistors are disposed. Devices included in the transistor region 18B may be electrically connected to a photodiode array 15B. For example, at least one of the reset transistor RX, the drive transistor DX, or the selection transistor SX of FIG. 2 may be disposed in the transistor region 18B.

The third layer 50B may include a logic region in which logic devices are disposed.

That is, the image sensor 10B may be a three-stack image sensor that includes three layers 30B, 40B and 50B.

Referring to FIGS. 9 to 11, the image sensor according to some example embodiments may further include a third substrate structure 300.

Referring to FIG. 9, the third substrate 310 may include a fifth surface 310a and a sixth surface 310b, which are opposite to each other. In some example embodiments, the fifth surface 310a of the third substrate 310 may be a surface facing the fourth surface 210b of the second substrate 210. A plurality of electronic devices may be disposed on the third substrate 310. For example, the third transistor TR3 may be disposed on the fifth surface 310a of the third substrate 310.

The third wiring structure IS3 may be disposed on the third substrate 310. For example, the third wiring structure IS3 may cover the fifth surface 310a of the third substrate 310. The third substrate 310 and the third wiring structure IS3 may constitute the third substrate structure 300. The third substrate structure 300 may correspond to the third layer 50B of FIG. 8.

The third wiring structure IS3 may include one or a plurality of wirings. For example, the third wiring structure IS3 may include a third inter-wire insulating layer 320 and a plurality of wirings 322, 324 and 326 in the third inter-wire insulating layer 320. In the drawing, the number of layers and arrangement of wirings constituting the third wiring structure IS3 are only exemplary, and are not limited thereto. The third inter-wire insulating layer 320 may include at least one of, for example, silicon oxide, silicon nitride, silicon oxynitride or a low dielectric constant (low-k) material having a dielectric constant lower than that of silicon oxide, but is not limited thereto.

At least a portion of the wirings 322, 324 and 326 of the third wiring structure IS3 may be connected to the third transistor TR3. In some example embodiments, the third wiring structure IS3 may include a seventh wiring 322 in the sensor array region SAR, an eighth wiring 324 in the connection region CR, and a ninth wiring 326 in the pad region PR. The seventh wiring 322, the eighth wiring 324 and the ninth wiring 326 may include at least one of, for example, tungsten (W), copper (Cu), aluminum (Al), gold (Au), silver (Ag) or their alloy, but are not limited thereto.

In some example embodiments, the second wiring structure IS2 may further include a third bonding layer 330. The third bonding layer 330 may be disposed on the second substrate 210. The third bonding layer 330 may cover a portion of the second surface 210b of the second substrate 210, and may be extended into the second substrate 210. The third wiring structure IS3 may further include a fourth bonding layer 430. The fourth bonding layer 430 may be disposed on the third inter-wire insulating layer 320. The fourth bonding layer 430 may cover a portion of an upper surface of the third inter-wire insulating layer 320. The fourth bonding layer 430 may be bonded to the third bonding layer 330. Accordingly, the third wiring structure IS3 may be attached to the second wiring structure IS2. For example, an upper surface of the fourth bonding layer 430 may be bonded to a lower surface of the third bonding layer 330.

For example, each of the third bonding layer 330 and the fourth bonding layer 430 may include at least one of silicon nitride or silicon carbonitride, but is not limited thereto.

A third bonding pad 351 may be formed in the second substrate 210. Also, a fourth bonding pad 451, which corresponds to the third bonding pad 351 and is exposed from the upper surface of the third inter-wire insulating layer 320, may be formed in the fourth bonding layer 430. When the third bonding layer 330 and the fourth bonding layer 430 are attached to each other, the third bonding pad 351 may be electrically connected to the fourth bonding pad 451. Accordingly, the second substrate structure 200 and the third substrate structure 300 may be electrically connected to each other. The third bonding pad 351 may be electrically connected to the fifth wiring 224 and/or the sixth wiring 226.

For example, the third bonding pad 351 and the fourth bonding pad 451 may include copper (Cu) and thus connected to each other in a Cu—Cu bonding method, but this is only exemplary. The third bonding pad 351 and the fourth bonding pad 451 may include aluminum (Al) or tungsten (W).

The third bonding pad 351 and the fourth bonding pad 451 are only shown as being formed in the connection region CR and the pad region PR, but this is only exemplary. For example, the third bonding pad 351 and the fourth bonding pad 451 may be formed in at least one of the pixel array region PA, the light blocking region OB, the connection region CR, or the pad region PR.

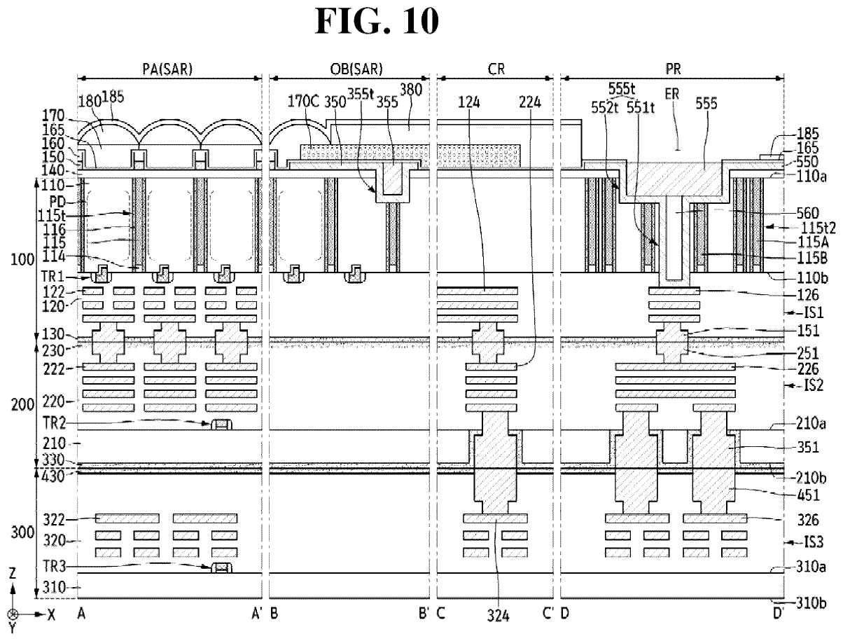

Referring to FIG. 10, there may be a plurality of first separation patterns 115A. When viewed in a plan view, the plurality of first separation patterns 115A may surround the second separation pattern 115B. Although not shown in detail, there may be also a plurality of second separation patterns 115B.

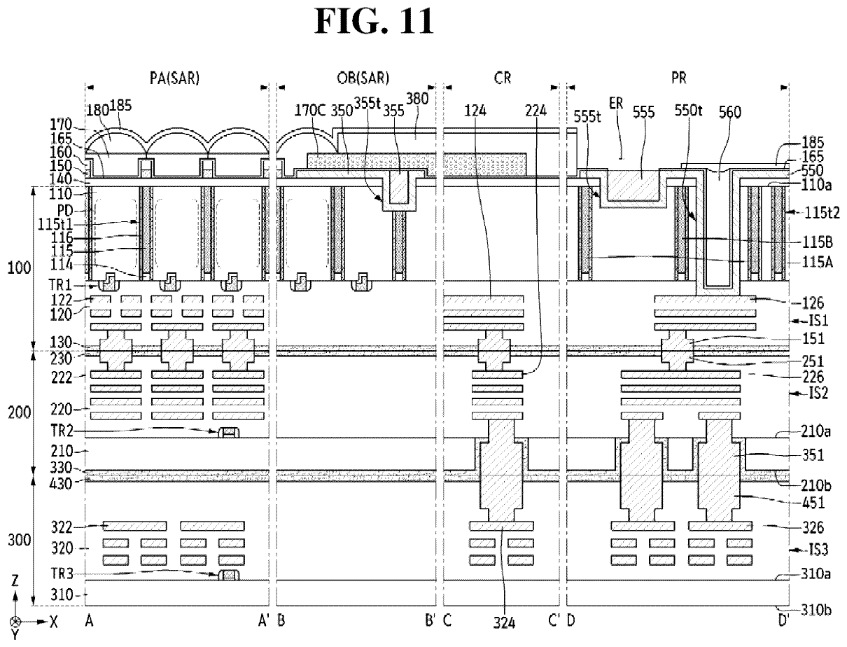

Referring to FIG. 11, the first via trench 555t may not overlap the second via trench 550t in the vertical direction. At least one of the second separation patterns 115B may be disposed between the first via trench 555t and the second via trench 550t.

FIGS. 12 and 13 are views illustrating an example layout of a pad region of an image sensor according to some example embodiments. For convenience of description, redundant portions of those described with reference to FIGS. 1 to 11 will be briefly described or omitted.

Referring to FIG. 12, when viewed in a plan view, a plurality of through via structures 550 may be disposed inside one second separation pattern 115B. When viewed in a plan view, the second separation pattern 115B may surround the plurality of through via structures 550.

Referring to FIG. 13, when viewed in a plan view, each through via structure 550 may be disposed inside each of the second separation patterns 115B. When viewed in a plan view, the second separation pattern 115B may surround one through via structure 550.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Although some example embodiments of the present disclosure have been described with reference to the accompanying drawings, it will be apparent to those skilled in the art that the present disclosure can be manufactured in various forms without being limited to the above-described example embodiments and can be embodied in other specific forms without departing from the technical spirits and essential characteristics. Thus, the above example embodiments are to be considered in all respects as illustrative and not restrictive.

What is claimed is:

1. An image sensor comprising:
a first substrate including a first surface and a second surface, which are opposite to each other;
a surface insulating film on the first surface of the first substrate;
a first wiring structure including a first wiring and a first inter-wire insulating layer on the second surface of the first substrate;
a first via trench, defined by the first substrate, at least partially extended into the surface insulating film and the first substrate;
a second via trench, defined by the first substrate, connected to the first via trench and extended into the first substrate, exposing at least a portion of the first wiring;
a pad pattern in the first via trench;
a through via structure connected to the pad pattern in the second via trench; and
a separation structure filling a separation pattern trench extended into the first substrate around the through via structure, the separation structure including
a first separation pattern around a sidewall of the first via trench, and
a second separation pattern between the sidewall of the first via trench and a sidewall of the second via trench, and
the second separation pattern spaced apart from the through via structure.

2. The image sensor of claim 1, wherein the second separation pattern is inside the first separation pattern when viewed in a plan view.

3. The image sensor of claim 1, wherein the through via structure is inside the second separation pattern when viewed in a plan view.

4. The image sensor of claim 1, wherein a distance between the first separation pattern and the through via structure is longer than a distance between the second separation pattern and the through via structure.

5. The image sensor of claim 1, wherein a length of the first separation pattern extended into the first substrate is longer than a length of the second separation pattern extended into the first substrate.

6. The image sensor of claim 1, wherein
the first separation pattern is extended between the surface insulating film and the second surface of the first substrate, and
the second separation pattern is extended between the pad pattern and the second surface of the first substrate.

7. The image sensor of claim 1, wherein a width of the first via trench is greater than a width of the second via trench.

8. The image sensor of claim 1, wherein the first via trench does not overlap the second via trench in a vertical direction.

9. The image sensor of claim 8, wherein the second separation pattern is between the first via trench and the second via trench.

10. The image sensor of claim 1, further comprising:
a second substrate on the first wiring structure, the second substrate including a third surface facing the second surface and a fourth surface opposite to the third surface;
a second wiring structure on the third surface of the second substrate, the second wiring structure including a second wiring and a second inter-wire insulating layer;
a first bonding structure on the first wiring structure, the first bonding structure including a first bonding layer and a first bonding pad; and
a second bonding structure on the second wiring structure, the second bonding structure including a second bonding layer and a second bonding pad,
wherein the first and second bonding layers are bonded to each other, and the first and second bonding pads are bonded to each other.

11. The image sensor of claim 1, further comprising:
a second substrate on the first wiring structure, the second substrate including a third surface facing the second surface and a fourth surface opposite to the third surface;
a second wiring structure on the third surface of the second substrate, the second wiring structure including a second wiring and a second inter-wire insulating layer;
a third substrate on the second wiring structure, the third substrate including a fifth surface facing the fourth surface and a sixth surface opposite to the fifth surface;
a third wiring structure on the fifth surface of the third substrate, the third wiring structure including a third wiring and a third inter-wire insulating layer;
a third bonding structure on the second wiring structure, the third bonding structure including a third bonding layer and a third bonding pad; and
a fourth bonding structure on the third wiring structure, the fourth bonding structure including a fourth bonding layer and a fourth bonding pad,
wherein the third and fourth bonding layers are bonded to each other, and the third and fourth bonding pads are bonded to each other.

12. The image sensor of claim 11, wherein the third bonding pad is in the second substrate and electrically connected to the second wiring.

13. An image sensor comprising:
a first substrate including a first region and a second region around the first region, and including a first surface and a second surface, which are opposite to each other;
photoelectric conversion layers in the first substrate of the first region;
a first separation structure between the photoelectric conversion layers, the first separation structure filling a first separation pattern trench extended into the first substrate;
a surface insulating film on the first surface of the first substrate;
a first wiring structure on the second surface of the first substrate, the first wiring structure including a first wiring and a first inter-wire insulating layer;
a first via trench defined by first substrate in the second region, the first via trench at least partially extended into the surface insulating film and the first substrate;
a second via trench defined by the first substrate and connected to the first via trench and extended into the first substrate, exposing at least a portion of the first wiring;
a pad pattern in the first via trench;
a through via structure connected to the pad pattern in the second via trench; and
a second separation structure, filling a second separation pattern trench extended into the first substrate, around the through via structure, the second separation structure including
a first separation pattern around a sidewall of the first via trench, and
a second separation pattern between the sidewall of the first via trench and a sidewall of the second via trench, and
each of the first and second separation patterns includes a material different from that of the surface insulating film.

14. The image sensor of claim 13, wherein a depth of the first separation pattern trench is a same depth as a depth of the second separation pattern trench.

15. The image sensor of claim 13, wherein a width of the first separation pattern trench is a same width as a width of the second separation pattern trench.

16. The image sensor of claim 13, wherein the first separation pattern is provided as a plurality of first separation patterns.

17. The image sensor of claim 13, wherein the second separation pattern is provided as a plurality of second separation patterns.

18. The image sensor of claim 13, wherein the first separation structure includes a same material as that of the second separation structure.

19. The image sensor of claim 13, wherein
the second separation structure includes a spacer film, a filling film, and a capping film in the second separation pattern trench,
the spacer film and the capping film include an insulating material, and
the filling film includes a conductive material.

20. An image sensor comprising:
a first substrate including a pixel array region, a light blocking region and a pad region, and including a first surface and a second surface, which are opposite to each other;
photoelectric conversion layers in the first substrate of the pixel array region;
a first separation structure between the photoelectric conversion layers;
a surface insulating film on the first surface of the first substrate;
grid patterns on the surface insulating film;
a color filter on the grid patterns;
a micro-lens on the color filter;
a first wiring structure on the second surface of the first substrate, the first wiring structure including a first wiring and a first inter-wire insulating layer;
a second substrate on the first wiring structure, the second substrate including a third surface facing the second surface and a fourth surface opposite to the third surface;
a second wiring structure on the third surface of the second substrate, the second wiring structure including a second wiring and a second inter-wire insulating layer;
a third substrate on the second wiring structure, the third substrate including a fifth surface facing the fourth surface and a sixth surface opposite to the fifth surface;
a third wiring structure on the fifth surface of the third substrate, the third wiring structure including a third wiring and a third inter-wire insulating layer;
a first via trench defined by the pad region, which is at least partially extended into the surface insulating film and the first substrate;
a second via trench exposing and defined by at least a portion of the first wiring connected to the first via trench and extended into the first substrate;
a pad pattern in the first via trench;
a through via structure connected to the pad pattern in the second via trench; and
a second separation structure, filling a separation pattern trench extended into the first substrate, around the through via structure, the second separation structure including
a first separation pattern around a sidewall of the first via trench, and
a second separation pattern between the sidewall of the first via trench and a sidewall of the second via trench, and
when viewed in a plan view, the second separation pattern is inside the first separation pattern, and the through via structure is inside the second separation pattern.
